(19) United States
(12) Patent Application Publication
(10) Pub. No.: US 2009/0004463 A1
(43) Pub. Date: Jan. 1, 2009

(54) REDUCING RESISTIVITY IN METAL INTERCONNECTS USING INTERFACE CONTROL

(76) Inventors: Michael Haverty, Mountain View, CA (US); Sadasivan Shankar, Cupertino, CA (US); Seongjun Park, San Jose, CA (US)

Correspondence Address: COOL PATENT, P.C.;c/o INTELLEVATE, P.O. BOX 52050, MINNEAPOLIS, MN, 55402, US

(21) Appl. No.: 11/769,108

(22) Filed: Jun. 27, 2007

(51) Int. Cl. B32B 15/04; B05D 1/36; C23C 16/00; C25D 3/00

(52) U.S. Cl. 428/333; 205/261; 427/250; 427/404; 428/332; 428/457

(57) ABSTRACT

Techniques for reducing resistivity in metal interconnects using interface control are generally described. In one example, an apparatus includes a dielectric substrate, a barrier film coupled with the dielectric substrate, a liner film of a selected material coupled with the barrier film, and a metal coupled with the liner film defining an interface region between the metal and the liner film, the material of the liner film being selected to provide an interface density of state about equal to or less than ten times the density of state of the metal in bulk form.

### TECHNICAL FIELD

Embodiments of the present invention are generally directed to the field of semiconductor fabrication and, more particularly, to reducing resistivity in metal interconnects.

### BACKGROUND

Generally, power required by an integrated circuit (IC) is proportional to the resistance of the circuit. In addition, signal delay such as resistive capacitive (RC) delay is limited by interconnect resistance. Problems associated with power consumption and signal delay are exacerbated as interconnect line widths are reduced. For example, the scaling of microelectronic circuits may reduce the thickness (t) of metal lines, which may increase the resistivity and resistance of metal lines in a roughly 1/t fashion. At reduced thickness, resistance is more sensitive to interface states in the interconnect lines, especially for lines smaller than 15 nm. Decreasing the resistance and resistivity of circuit materials may reduce power consumption and increase the speed at which a circuit switches.

### BRIEF DESCRIPTION OF THE DRAWINGS

Embodiments of the present invention are illustrated by way of example, and not by way of limitation, in the figures of the accompanying drawings in which like reference numerals refer to similar elements and in which:

FIG. 1 is a schematic of a film arrangement in a microelectronic device, according to but one embodiment;

FIG. 2 is a model graph of density of state at different energies for a Ta/Cu system, according to but one embodiment;

FIG. 3 is a process schematic of two deposition methods, according to but one embodiment; and

FIG. 4 is a diagram of an example system in which embodiments of the present invention may be used, according to but one embodiment.

It will be appreciated that for simplicity and/or clarity of illustration, elements illustrated in the figures have not necessarily been drawn to scale. For example, the dimensions of some of the elements may be exaggerated relative to other elements for clarity. Further, if considered appropriate, reference numerals have been repeated among the figures to indicate corresponding and/or analogous elements.

### DETAILED DESCRIPTION

Embodiments of using interface control to reduce resistivity in metal interconnects are described herein. In the following description, numerous specific details are set forth to provide a thorough understanding of embodiments of the invention. One skilled in the relevant art will recognize, however, that the invention can be practiced without one or more of the specific details, or with other methods, components, materials, and so forth. In other instances, well-known structures, materials, or operations are not shown or described in detail to avoid obscuring aspects of the specification.

Reference throughout this specification to “one embodiment” or “an embodiment” means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment. Furthermore, the particular features, structures or characteristics may be combined in any suitable manner in one or more embodiments.

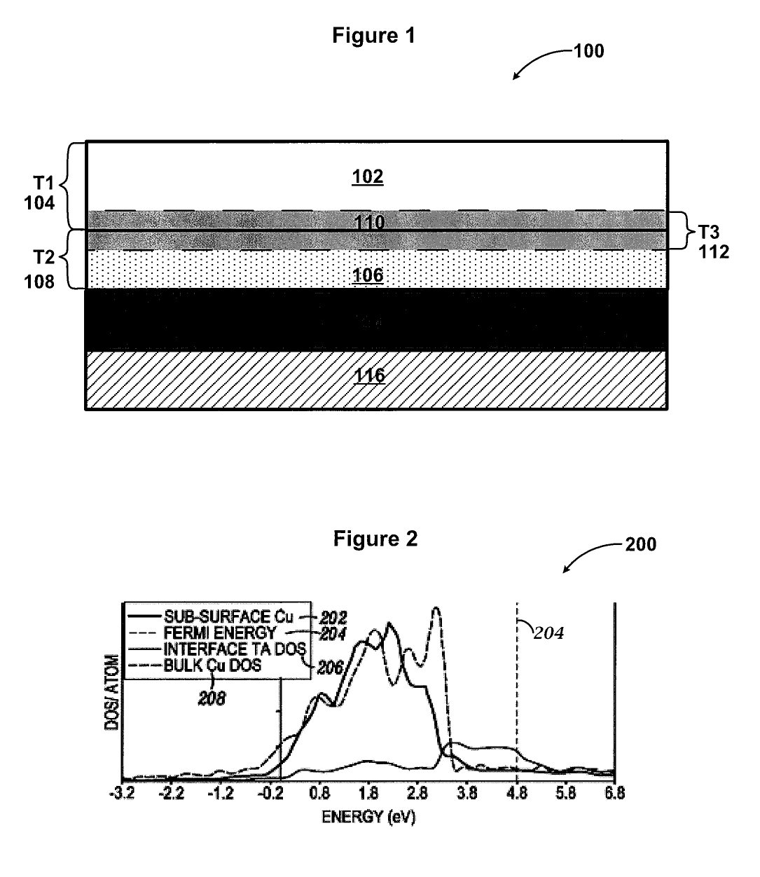

FIG. 1 is a schematic of a film arrangement in a microelectronic device 100, according to but one embodiment. In an embodiment, an apparatus 100 includes a metal 102 having a thickness (T1) 104, a liner film 106 of a selected material having a thickness (T2) 108, and interface region 110 having a thickness (T3) 112, each coupled as shown. In one embodiment, liner film 106 is coupled with a barrier film 114, and barrier film 114 is coupled with a dielectric substrate 118. In another embodiment, an apparatus 100 includes a dielectric substrate 118, a barrier film 114 coupled with the dielectric substrate 118, a liner film 106 of a selected material coupled with the barrier film 114, and a metal 102 coupled with the liner film 106 defining an interface region 110 between the metal 102 and the liner film 106.

Using a liner film 106 material selected to reduce the change in electronic structure of metal 102 at the interface 110 may reduce resistivity in a microelectronic device 100. In an embodiment, the material of the liner film 102 is selected to provide an interface 110 density of state about equal to or less than the density of state of the metal 102 in bulk form. The density of state may refer to the number of electron states available for a particular energy. One electron may have a density of state of two, one for each spin. In another embodiment, the liner film material 106 is selected to have a density of state at the interface 110 Fermi energy that is about equal to or less than the density of state of the metal 102 in bulk form.

In one embodiment, the metal 102 is Cu and the barrier film 114 is TaN. In another embodiment where the metal 102 is Cu and the barrier film 114 is TaN, the liner film material 106 is selected to have a density of state at the Fermi energy of an interface region 110 that is equal to or less than about 5-10 times the density of state at the Fermi energy of bulk Cu. In other embodiments, the metal 102 is Al, Ag, Au or any other conductive metal. In another embodiment, metal 102 is an interconnect of an integrated circuit (IC). According to an embodiment, metal 102 has a thickness, T1, of about 60 nanometers or less.

Liner film 106 materials may include metals, dielectrics, semiconductors, oxides, ceramics, and/or alloys among other materials. In an embodiment, the liner film 106 material includes B₄C, Si₃N₄, C, SiO₂, SiC, HfO₂, Al, Ag, Au, Ta₂O₅, Al₂O₃, Be, ZrO₂, MgO, Cd, RuSn, CuSi, Sn, Zn, HfC, TaSi₂, TaO, ZrN, ZrC, HfN, CuO, TaN, MoSi₂, HfSi₂, WSi₂, TiN, NbC, NbSi₂, ZrSi₂, WC, TaO₂, or Mo₂C. Such materials may provide an interface 110 density of state about equal to or less than ten times the density of state of the metal 102 in bulk form. In another embodiment, liner film 106 includes a suitable combination of the example materials provided above. A material for liner film 106 is not limited to the listed example materials and may include other materials that accord with previously described embodiments of a liner film 106 material. In an embodiment, liner film 106 has a thickness T2 that is less than metal thickness T1. Interface region 110 may have a thickness T3 that includes an area of metal 102 and liner film 106 that is about 3-8 atomic layers thick. In an embodiment, interface region 110 includes an area that is affected by density of state effects of liner film 106 on metal 102. Embodiments of thicknesses for T1, T2, and T3 have been provided to show the relative scale of features described herein; however, the thicknesses are not necessarily limited to the values in the provided examples.

Dielectric substrate 118 may include one or more surfaces that define an inter-layer dielectric (ILD) trench or via that has been patterned and/or etched into the substrate as part of a semiconductor fabrication process. Although FIG. 1 depicts a stack of layers in a particular orientation, no particular orientation is required or implied. For example, dielectric substrate 118 may include a sidewall of a trench or via in one embodiment.

Other electronic elements, components, and/or systems may be coupled with the film arrangement of a microelectronic device 100. An example of such a system is shown and described with respect to FIG. 5.

FIG. 2 is a model graph 200 of density of state (DOS) at different energies for sub-surface Cu 202, interface Ta 206, and bulk Cu 208 in a Ta/Cu system, according to but one embodiment. Interface system Fermi energy 204 is also depicted for bulk Cu. In an embodiment, sub-surface Cu 202 corresponds with metal 102 within region 110 and Ta corresponds with barrier film 114 where liner film 106 isn't used and barrier film 114 is adjacent to metal 102.

Graph 200 shows how a sub-surface Cu atom 202 that is three atomic layers away from a Ta/Cu interface has a DOS that is different from that of bulk Cu 208 both qualitatively and quantitatively. Such altered electronic structure of the Ta/Cu system may be caused by the electron d-states of Ta 206 bonding with the Cu electronic states near the Fermi energy of Cu 204 and changing the local DOS character of sub-surface Cu 202. The partial DOS of Ta 206 at the Ta/Cu interface shows that the Ta d-states range of energy includes the interface system Fermi energy 204.

The overall morphology of the DOS near the Fermi energy of bulk Cu 204 is critical to the resistivity of Cu. Electrons involved in conduction are primarily the electrons within a few k_{B}T of the Fermi energy at temperature T (where k_{B} is Boltzmann's constant=8.617343×10⁻⁵ eV/K). In one embodiment, electrons involved in conduction are primarily the electrons that are less than 0.075 eV from the Fermi energy at 300 K.

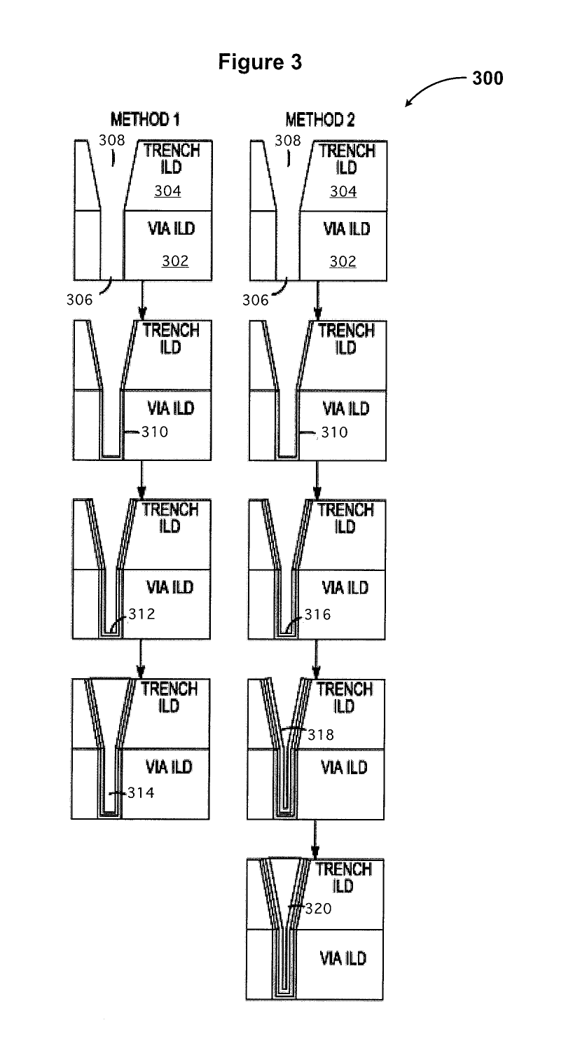

FIG. 3 is a process schematic of deposition methods 300, according to but one embodiment. In one embodiment, process schematic 300 includes deposition Method 1 and Method 2 for depositing a barrier film 310 to a dielectric substrate 302, 304, depositing a liner film 312, 316 of a selected material to the barrier film 310, and depositing a metal 314, 318, 320 to the liner film 312, 316, with arrows indicating an example process flow. In one embodiment, depositing a liner film 312, 316 of a selected material to the barrier film 310 includes depositing a liner film 312, 316 of a material selected to provide an interface density of state about equal to or less than the density of state of a metal 314, 320 in bulk form to the barrier film 310, the interface being between the liner film 312, 316 and a metal 314, 318, 320.

In an embodiment, Method 1 of FIG. 3 includes preparing a via inter-layer dielectric (ILD) 302, trench ILD 304, via 306, and trench 308 for deposition of a barrier film 310, each coupled as shown. In an embodiment, via ILD 302, trench ILD 304, via 306, and trench 308 are part of a dual damascene structure or patterned ILD trench. In other embodiments, Method 1 may be applied to one or more vias and/or trenches that are not part of a dual damascene structure.

In an embodiment, Method 1 includes depositing a barrier film 310 to a dielectric substrate including via ILD 302 and/or trench ILD 304. Barrier film 310 may comprise any suitable material that adequately prevents diffusion or cross-contamination of metal 314, 318, 320 with other materials external to the diffusion barrier 310. Barrier film 310 may be deposited by any suitable thin films deposition process. In one embodiment, barrier film 310 includes TaN.

In an embodiment, Method 1 includes depositing a liner film 312 of a selected material to the barrier film 310. In an embodiment, liner film 312 material is selected to provide an interface density of state about equal to or less than the density of state of a metal 314 in bulk form, the interface being between the liner film 312 and a metal 314 that is to be deposited to the liner film 312. In another embodiment, liner film 312 material is selected to have a density of state at the interface Fermi energy that is about equal to or less than the density of state of a metal 314 in bulk form, the interface being between the liner film 312 and a metal 314 that is to be deposited to the liner film 312. In another embodiment, liner film 312 material is selected to have a density of state at the Fermi energy of an interface region that is equal to or less than about 5-10 times the density of state at the Fermi energy of a metal 314 in bulk form, the interface being between the liner film 312 and a metal 314 that is to be deposited to the liner film 312.

In an embodiment, liner film 312 material is selected to include one or more of the following: B₄C, Si₃N₄, C, SiO₂, SiC, HfO₂, Al, Ag, Au, Ta₂O₅, Al₂O₃, Be, ZrO₂, MgO, Cd, RuSn, CuSi, Sn, Zn, HfC, TaSi₂, TaO, ZrN, ZrC, HfN, CuO, TaN, MoSi₂, HfSi₂, WSi₂, TiN, NbC, NbSi₂, ZrSi₂, WC, TaO₂, and Mo₂C. In an embodiment, the preceding example materials are selected as a liner film 312 material where the metal 314 is Cu and the barrier film 310 is TaN. A liner film 312 material is not limited to these example materials, however, and may vary according to the metal 314 to be deposited and the metal's associated electronic properties including density of state. A liner film 312 material may be deposited by any suitable method including, but not limited to, sputtering, atomic layer deposition (ALD), and/or chemical vapor deposition (CVD) techniques.

Method 1 may be a method suitable for a liner film 312 material that is conductive enough to enable electroplating deposition of a metal 314 directly to the liner film 312 material. According to one embodiment, Method 1 includes depositing an electrically conductive liner film material 312.

In an embodiment, Method 1 includes depositing a metal 314 to a liner film 312, creating an interface region between the metal 314 and the liner film 312. Depositing a metal 314 to a liner film 312 includes using an electroplating process, according to one embodiment. A metal 314 deposition process may include electroplating, chemical vapor deposition (CVD), physical vapor deposition (PVD), atomic layer deposition (ALD), plasma-enhanced vapor deposition, sputtering, any other suitable deposition method, or any suitable combination thereof.

According to an embodiment, Method 2 of FIG. 3 accords with embodiments already described for Method 1 except that the liner film 316 in Method 2 may include a material that is not conductive enough to enable electroplating deposition of a metal 320 directly to the liner film 316 material. The resistivity of liner film 316 material may prohibit metal 320 electrodeposition. In this regard, Method 2 may be a method suitable for a liner film 316 that is dielectric or semi-conductive. In an embodiment, Method 2 includes depositing a dielectric or semi-conductive liner film 316.

In an embodiment, Method 2 includes depositing a thin film of a metal 318 to the liner film 316. Thin film 318 deposition may be accomplished by PVD, CVD, ALD, or any other suitable thin film deposition technique. In an embodiment, Method 2 includes depositing a thin film of a metal 318 by physical vapor deposition (PVD). Deposition of a thin film of metal 318 may enable further deposition of a metal 320 by an electroplating process. In an embodiment, depositing additional metal 320 to the thin film 318 metal is accomplished by an electroplating process. Other suitable metal 320 deposition techniques may be used in other embodiments.

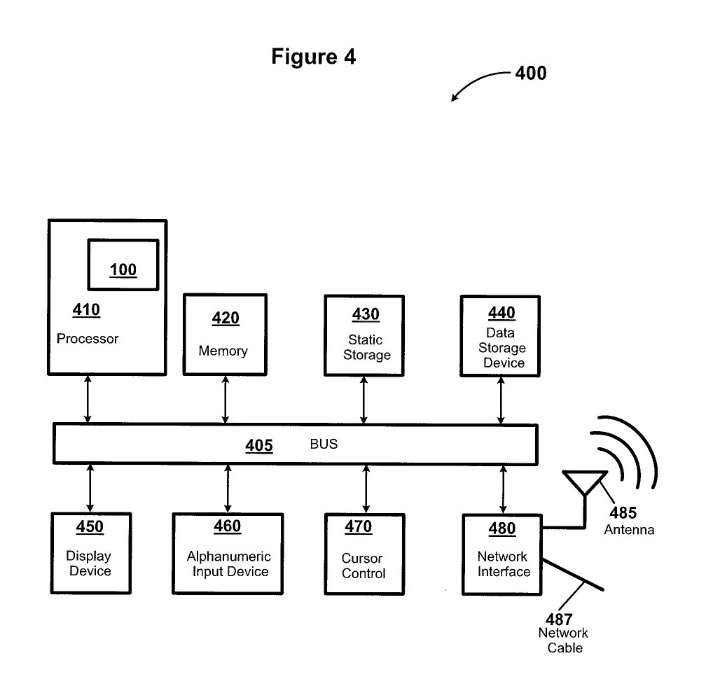

FIG. 4 is a diagram of an example system in which embodiments of the present invention may be used, according to but one embodiment. System 400 is intended to represent a range of electronic systems (either wired or wireless) including, for example, desktop computer systems, laptop computer systems, personal computers (PC), wireless telephones, personal digital assistants (PDA) including cellular-enabled PDAs, set top boxes, pocket PCs, tablet PCs, DVD players, or servers, but is not limited to these examples and may include other electronic systems. Alternative electronic systems may include more, fewer and/or different components.

In one embodiment, electronic system 400 includes a film arrangement in a microelectronic device 100 that accords with embodiments described with respect to in FIG. 1. In an embodiment, film arrangement 100 is part of an interconnect feature of an integrated circuit (IC) such as a processor 410, the IC being coupled with one or more electronic systems 400. In other embodiments, electronic system 400 is coupled with an interconnect apparatus 100 that accords with embodiments already described for FIGS. 1-3.

Electronic system 400 may include bus 405 or other communication device to communicate information, and processor 410 coupled to bus 405 that may process information. While electronic system 400 is illustrated with a single processor, system 400 may include multiple processors and/or co-processors. System 400 may also include random access memory (RAM) or other storage device 420 (may be referred to as memory), coupled to bus 405 and may store information and instructions that may be executed by processor 410.

Memory 420 may also be used to store temporary variables or other intermediate information during execution of instructions by processor 410. Memory 420 is a flash memory device in one embodiment.

System 400 may also include read only memory (ROM) and/or other static storage device 430 coupled to bus 405 that may store static information and instructions for processor 410. Data storage device 440 may be coupled to bus 405 to store information and instructions. Data storage device 440 such as a magnetic disk or optical disc and corresponding drive may be coupled with electronic system 400.

Electronic system 400 may also be coupled via bus 405 to display device 450, such as a cathode ray tube (CRT) or liquid crystal display (LCD), to display information to a user. Alphanumeric input device 460, including alphanumeric and other keys, may be coupled to bus 405 to communicate information and command selections to processor 410. Another type of user input device is cursor control 470, such as a mouse, a trackball, or cursor direction keys to communicate information and command selections to processor 410 and to control cursor movement on display 450.

Electronic system 400 further may include one or more network interfaces 480 to provide access to network, such as a local area network. Network interface 480 may include, for example, a wireless network interface having antenna 485, which may represent one or more antennae. Network interface 480 may also include, for example, a wired network interface to communicate with remote devices via network cable 487, which may be, for example, an Ethernet cable, a coaxial cable, a fiber optic cable, a serial cable, or a parallel cable.

In one embodiment, network interface 480 may provide access to a local area network, for example, by conforming to an Institute of Electrical and Electronics Engineers (IEEE) standard such as IEEE 802.11b and/or IEEE 802.11g standards, and/or the wireless network interface may provide access to a personal area network, for example, by conforming to Bluetooth standards. Other wireless network interfaces and/or protocols can also be supported.

IEEE 802.11b corresponds to IEEE Std. 802.11b-1999 entitled “Local and Metropolitan Area Networks, Part 11: Wireless LAN Medium Access Control (MAC) and Physical Layer (PHY) Specifications: Higher-Speed Physical Layer Extension in the 2.4 GHz Band,” approved Sep. 16, 1999 as well as related documents. IEEE 802.11g corresponds to IEEE Std. 802.11g-2003 entitled “Local and Metropolitan Area Networks, Part 11: Wireless LAN Medium Access Control (MAC) and Physical Layer (PHY) Specifications, Amendment 4: Further Higher Rate Extension in the 2.4 GHz Band,” approved Jun. 27, 2003 as well as related documents. Bluetooth protocols are described in “Specification of the Bluetooth System: Core, Version 1.1,” published Feb. 22, 2001 by the Bluetooth Special Interest Group, Inc. Previous or subsequent versions of the Bluetooth standard may also be supported.

In addition to, or instead of, communication via wireless LAN standards, network interface(s) 480 may provide wireless communications using, for example, Time Division, Multiple Access (TDMA) protocols, Global System for Mobile Communications (GSM) protocols, Code Division, Multiple Access (CDMA) protocols, and/or any other type of wireless communications protocol.

In an embodiment, a system 400 includes one or more omnidirectional antennae 485, which may refer to an antenna that is at least partially omnidirectional and/or substantially omnidirectional, a processor 410 coupled to communicate via the antennae, the processor including film arrangement 100 as described herein.

Various operations may be described as multiple discrete operations in turn, in a manner that is most helpful in understanding the invention. However, the order of description should not be construed as to imply that these operations are necessarily order dependent. In particular, these operations need not be performed in the order of presentation. Operations described may be performed in a different order than the described embodiment. Various additional operations may be performed and/or described operations may be omitted in additional embodiments.

The above description of illustrated embodiments of the invention, including what is described in the Abstract, is not intended to be exhaustive or to limit the invention to the precise forms disclosed. While specific embodiments of, and examples for, the invention are described herein for illustrative purposes, various equivalent modifications are possible within the scope of this description, as those skilled in the relevant art will recognize.

These modifications can be made in light of the above detailed description. The terms used in the following claims should not be construed to limit the invention to the specific embodiments disclosed in the specification and the claims. Rather, the scope of the invention is to be determined entirely by the following claims, which are to be construed in accordance with established doctrines of claim interpretation.

What is claimed is:

1. An apparatus comprising:
a dielectric substrate;
a barrier film coupled with the dielectric substrate;
a liner film of a selected material coupled with the barrier film; and
a metal coupled with the liner film defining an interface region between the metal and the liner film, the material of the liner film being selected to provide an interface density of state about equal to or less than ten times the density of state of the metal in bulk form.

2. An apparatus according to claim 1 wherein the liner film material is selected to have a density of state at the interface Fermi energy that is about equal to or less than ten times the density of state of the metal in bulk form.

3. An apparatus according to claim 1 wherein the metal comprises Cu and the barrier film comprises TaN.

4. An apparatus according to claim 1 wherein the liner film material comprises B₄C, Si₃N₄, C, SiO₂, SiC, HfO₂, Al, Ag, Au, Ta₂O₅, Al₂O₃, Be, ZrO₂, MgO, Cd, RuSn, CuSi, Sn, Zn, HfC, TaSi₂, TaO, ZrN, ZrC, HfN, CuO, TaN, MoSi₂, HfSi₂, WSi₂, TiN, NbC, NbSi₂, ZrSi₂, WC, TaO₂, or, Mo₂C, or suitable combinations thereof.

5. An apparatus according to claim 1 wherein the metal is an interconnect of an integrated circuit, the metal having a thickness of about 60 nanometers or less.

6. An apparatus according to claim 5 further comprising:
one or more electronic systems coupled with the integrated circuit

7. An apparatus according to claim 1 wherein the interface region is about 6 atomic layers thick.

8. A method comprising:
depositing a barrier film to a dielectric substrate;
depositing a liner film of a selected material to the barrier film; and
depositing a metal to the liner film, the liner film being selected to provide an interface density of state about equal to or less than ten times the density of state of the metal in bulk form, the interface being between the metal and the liner film.

9. A method according to claim 8 wherein the liner film material is selected to have a density of state at the interface Fermi energy that is about equal to or less than ten times the density of state of the metal in bulk form.

10. A method according to claim 8 wherein the metal comprises Cu and the barrier film comprises TaN.

11. A method according to claim 8 wherein the liner film material comprises B₄C, Si₃N₄, C, SiO₂, SiC, HfO₂, Al, Ag, Au, Ta₂O₅, Al₂O₃, Be, ZrO₂, MgO, Cd, RuSn, CuSi, Sn, Zn, HfC, TaSi₂, TaO, ZrN, ZrC, HfN, CuO, TaN, MoSi₂, HfSi₂, WSi₂, TiN, NbC, NbSi₂, ZrSi₂, WC, TaO₂, or, Mo₂C, or suitable combinations thereof.

12. A method according to claim 8 wherein depositing a liner film comprises depositing a dielectric or semi-conductive material and wherein depositing a metal comprises:
depositing a thin film of the metal to the liner film by physical vapor deposition; and
depositing additional metal to the thin film of metal using an electroplating process.

13. A method according to claim 8 wherein depositing a liner film comprises depositing an electrically conductive material and wherein depositing a metal comprises using an electroplating process.
